(19) United States
(12) Patent Application Publication
(10) Pub. No.: US 2013/0146346 A1
(43) Pub. Date: Jun. 13, 2013

(54) PHOTOSENSITIVE COMPOSITION FOR TRANSPARENT CONDUCTIVE FILM

(71) Applicant: JNC CORPORATION, Tokyo (JP)

(72) Inventors: KEIICHI NAKAMOTO, CHIBA (JP); MOTOKI YANAI, CHIBA (JP); SETSUO ITAMI, CHIBA (JP)

(73) Assignee: JNC CORPORATION, TOKYO (JP)

(21) Appl. No.: 13/707,553

(22) Filed: Dec. 6, 2012

(30) Foreign Application Priority Data
Dec. 8, 2011 (JP) 2011-269175
Oct. 24, 2012 (JP) 2012-234825

(51) Int. Cl. G03F 7/004; H05K 1/03

(52) U.S. Cl. CPC G03F 7/004; H05K 1/0353
USPC 174/258; 430/280.1; 430/313; 430/311

(57) ABSTRACT

A photosensitive composition for forming a photosensitive protective film is described which can provide a transparent conductive film including a nanostructure with a high hardness and environmental resistance. The photosensitive composition contains a compound having a dicyclopentadiene skeleton and an epoxy group or oxetanyl group as a first component, a compound including an (meth)acryl group in a molecule as a second component, an alkali-soluble polymer as a third component, and a solvent as a fourth component.

### CROSS-REFERENCE TO RELATED APPLICATIONS

This application claims the priority benefit of Japan Patent Application No. 2011-269175, filed on Dec. 8, 2011 and Japan Patent Application No. 2012-234825, filed on Oct. 24, 2012. The entirety of each of the above-mentioned patent applications is hereby incorporated by reference herein and made a part of this specification.

### TECHNICAL FIELD

The present invention relates to a photosensitive composition for forming a protective film for a transparent conductive film including a nanostructure. More specifically, the invention relates to a method for manufacturing a protective film having a high hardness, environmental resistance, and patternability for a transparent conductive film as obtained from the composition, and a device element using the protective film.

### BACKGROUND ART

A transparent conductive film is used in various fields such as a transparent electrode for a liquid crystal display (LCD), a plasma display panel (PDP), an organic electroluminescence display, a photovoltaic (PV) cell and a touch panel (TP), an electrostatic dissipative (ESD) film and an electromagnetic interference (EMI) film. As the transparent conductive films, a film prepared using indium tin oxide (ITO) has been used so far. However, ITO has had a problem of a low supply stability of indium, a high manufacturing cost, a lack in flexibility, and generation of a large amount of heat during film formation. Therefore, a search has been actively conducted for a transparent conductive film that can be prepared using a material in place of ITO. Among types of the films, a transparent conductive film including a nanostructure is optimum as an ITO substitute transparent conductive film in view of conductivity, optical characteristics, manufacturing cost, flexibility and no need of a high temperature during film formation, or the like. For example, a transparent conductive film including metallic nanowires and having a high conductivity, optical characteristics and flexibility is known (Patent literature No. 1 and Non-patent literature No. 1, for example).

However, the transparent conductive film including the nanostructure has had a problem of a low film hardness, and a lack in durability in a general manufacturing process, namely, a lack in hardness and environmental resistance due to an easy degradation of characteristics as caused by easy reaction with various compounds. Therefore, many attempts have been conducted for laminating a protective film onto a surface of the transparent conductive film including the nanostructure to improve hardness and environmental resistance. Moreover, such a protective film and a transparent conductive film are generally subjected to patterning using a technique such as photolithography and used in many cases. Thus, a protective film having photosensitivity and patternability is required for reducing the number of processes relating to the films. More specifically, such a photosensitive protective film is needed that can improve the hardness and the environmental resistance of the transparent conductive film including the nanostructure to allow patterning of the protective film, or the transparent conductive film including the nanostructure.

Several examples of such a photosensitive protective film for the transparent conductive films including the nanostructure have been reported. However, any films have been quite difficult to suitably use due to a lack in hardness, environmental resistance, or patternablity of the transparent conductive film.

### CITATION LIST

### Patent Literature

Patent literature No. 1: JP 2010-507199 A.

### Non-Patent Literature

Non-patent literature No. 1: Shih-Hsiang Lai, Chun-Yao Ou, “SID 08 DIGEST,” 2008, pp. 1200-1202.

### SUMMARY OF INVENTION

### Technical Problem

In view of the background described above, an objective of the invention is to provide a photosensitive composition for forming a photosensitive protective film that can provide a transparent conductive film including a nanostructure with a high hardness and environmental resistance. The protective film can be subjected to patterning, and the transparent conductive film having the nanostructure can also be subjected to patterning by using the protective film depending on an application.

### Solution to Problem

The present inventors have diligently continued to conduct research for solving the problems described above, as a result, have found a fact that a protective film formed using a photosensitive composition containing a compound having a dicyclopentadiene skeleton and an epoxy group or oxetanyl group as a first component, a compound including a (meth)acryl group in a molecule as a second component and an alkali-soluble polymer as a third component has high characteristics as a photosensitive protective film for a transparent conductive film including a nanostructure, and have completed the invention based on the finding.

The invention concerns a photosensitive composition that is used as a protective film for a transparent conductive film including a nanostructure, and contains a compound including a structure represented by general formula (I) in a molecule and having an epoxy group or oxetanyl group in the molecule as a first component, a compound including a (meth)acryl group in the molecule as a second component, an alkali-soluble polymer as a third component, and a solvent as a fourth component:

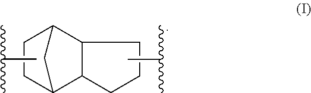

The invention also concerns a method for forming a protective film for a transparent conductive film including a nanostructure, including:

process 1 for applying the photosensitive composition described above onto the transparent conductive film including the nanostructure to obtain a coating;
process 2 for drying the coating;
process 3 for irradiating the coating with light through a photomask;
process 4 for developing the coating using a developer; and
process 5 for heating the coating.

The invention further concerns a method for patterning a transparent conductive film including a nanostructure, applying the method described above, further containing a process for etching the transparent conductive film including the nanostructure by using an acidic solution in and after process 4.

The invention still further concerns a laminate including a film formed by the method described above, a transparent conductive film including a nanostructure, and a substrate, wherein surface resistance of the transparent conductive film is in the range of 10 ohms/square (hereinafter, occasionally expressed in terms of Ω/□ for ohms/square) to 500Ω/□, a total luminous transmittance of the laminate is 85% or more, and a haze of the laminate is 3% or less.

The invention furthermore concerns an electronic device using the laminate described above.

The invention has a constitution as described below.

Item 1. A photosensitive composition that is used as a protective film for a transparent conductive film including a nanostructure, and contains
a compound including a structure represented by general formula (I) in a molecule and having an epoxy group or oxetanyl group in the molecule as a first component,
a compound including a (meth)acryl group in the molecule as a second component,
an alkali-soluble polymer as a third component, and
a solvent as a fourth component:

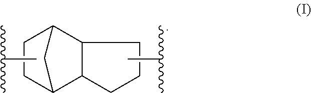

Item 2. The photosensitive composition according to item 1, used for patterning of the transparent conductive film including the nanostructure.
Item 3. The photosensitive composition according to item 1 or 2, wherein an equivalent of the epoxy group or oxetanyl group of the first component is 200 or more, and the number of the epoxy groups or oxetanyl groups in one molecule is 2 or more.
Item 4. The photosensitive composition according to any one of items 1 to 3, wherein the first component is a compound represented by general formula (I-a):

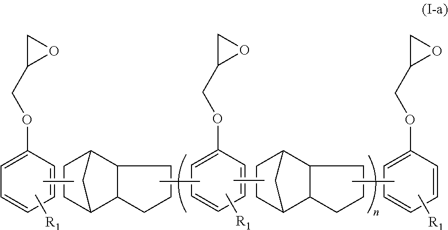

wherein R₁ in formula (I-a) is each independently hydrogen or a hydrocarbon group having 1 to 12 carbons, and n is an integer from 1 to 10 to represent a repeating unit.
Item 5. The photosensitive composition according to any one of items 1 to 4, wherein the second component is a compound represented by general formula (II-a):

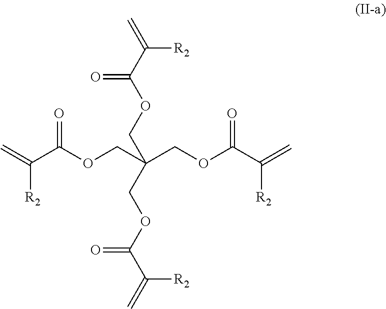

wherein R₂ in formula (II-a) is each independently hydrogen or an alkyl group having 1 to 4 carbons.
Item 6. The photosensitive composition according to any one of items 1 to 5, wherein the third component is a polymer obtained by copolymerizing a mixture containing a radically polymerizable monomer having a carboxyl group.
Item 7. The photosensitive composition according to item 6, wherein the third component is a polymer obtained by copolymerizing a mixture containing (meth)acrylic acid, N-cyclohexylmaleimide and dicyclopentanyl(meth)acrylate.
Item 8. The photosensitive composition according to any one of items 1 to 7, wherein a ratio of the first component is in the range of 1 to 10% by weight, a ratio of the second component is in the range of 1 to 10% by weight, a ratio of the third component is in the range of 1 to 10% by weight, and a ratio of the fourth component is in the range of 70 to 97% by weight, based on the total amount of the photosensitive composition.
Item 9. The photosensitive composition according to any one of items 1 to 8, further containing a photopolymerization initiator.
Item 10. The photosensitive composition according to any one of items 1 to 9, wherein the nanostructure includes silver nanowires.
Item 11. The photosensitive composition according to item 10, wherein a mean of length of the silver nanowires in a minor axis is in the range of 5 nanometers to 100 nanometers, and a mean of length of the silver nanowires in a major axis is in the range of 2 micrometers to 50 micrometers.
Item 12. A method for forming a protective film for a transparent conductive film including a nano structure, including:
process 1 for applying the photosensitive composition according to any one of items 1 to 11 onto the transparent conductive film including the nanostructure to obtain a coating;

process 2 for drying the coating;

process 3 for irradiating the coating with light through a photomask;

process 4 for developing the coating using a developer; and

process 5 for heating the coating.
Item 13. A method for patterning a transparent conductive film including a nanostructure, applying the method according to item 12, further containing a process for etching the transparent conductive film including the nanostructure by using an acidic solution after process 4 according to item 12.
Item 14. The method for patterning the transparent conductive film according to item 13, wherein the acidic solution contains phosphoric acid.
Item 15. The method according to item 12, wherein a heating temperature is 160° C. or lower in process 5 according to item 12.
Item 16. The method for patterning the transparent conductive film according to item 13 or 14, wherein a heating temperature is 160° C. or lower in process 5 according to item 12.
Item 17. A laminate including a film formed by the method according to any one of items 12 to 16, a transparent conductive film including a nanostructure, and a substrate, wherein surface resistance of the transparent conductive film is in the range of 10Ω/□ to 500Ω/□, a total luminous transmittance of the laminate is 85% or more, and a haze of the laminate is 3% or less.
Item 18. An electronic device using the laminate according to item 17.

### ADVANTAGEOUS EFFECTS OF INVENTION

A protective film formed using a photosensitive composition according to one aspect in a preferred embodiment of the invention can provide a transparent conductive film including a nanostructure with a high hardness and environmental resistance, and the protective film or the transparent conductive film including the nanostructure can be satisfactorily subjected to patterning. Therefore, the composition can be valuably used as a photosensitive protective film for the transparent conductive film including the nanostructure.

### DESCRIPTION OF EMBODIMENTS

Hereinafter, the invention will be specifically explained.

### 1. Photosensitive Composition

### 1-1. First Component

A first component contained in a photosensitive composition of the invention is a compound having a structure represented by general formula (I) (hereinafter, abbreviated as a dicyclopentadiene structure) in a molecule, and an epoxy group or oxetanyl group (hereinafter, occasionally abbreviated as a reactive cyclic ether group as a generic term for the epoxy group and the oxetanyl group) in the molecule:

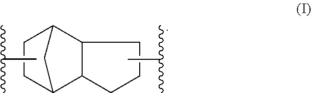

A protective film for a transparent conductive film including a nanostructure as formed using the photosensitive composition containing the first component according to the invention provides the transparent conductive film with a high hardness and environmental resistance, and has high shielding properties against an acidic solution. The reason is presumed such that the dicyclopentadiene structure of the first component has a high rigidity and steric structure and the reactive cyclic ether group of the first component has a high reactivity, and therefore a three-dimensionally and sterically cross-linked body to be formed by a reaction between the first components or between the first component and a third component during calcination has an excellent heat resistance and hardness, a low moisture absorption, high shielding properties against the acidic solution, and so forth.

In general, the transparent conductive film including the nanostructure has a high solubility in an etchant or the like due to a high reactivity of the nanostructure. Thus, a resist having high shielding properties is needed upon patterning of the conductive film. The protective film formed using the photosensitive composition of the invention has excellent shielding properties against the acidic solution. Therefore, if the protective film is used as the resist to be used for patterning of the transparent conductive film including the nanostructure, patterning can be performed with a high resolution.

The reactive cyclic ether group of the first component does not need to wholly react, but only needs to partially react.

A compound that can be used for the first component includes an epoxy resin having the dicyclopentadiene structure, for example. Among types of the compounds, a multifunctional epoxy resin having a repeating unit is preferred. Such an epoxy resin is schematically represented by formula (A). In the formula, X and X′ are a skeleton constituted of an arbitrary element, Y is a repeating skeleton including the dicyclopentadiene structure and the epoxy group, and n is an integer of 1 or more to represent a repeating unit.

The epoxy resins are excellent in view of lowness of manufacturing cost and ease of a molecular design. Thus, a compound having optimum physical properties as the first component of the photosensitive composition according to the invention can be easily synthesized by designing Y as the repeating skeleton and controlling n as the number of repetition. From a viewpoint of ease of manufacture, X and X′ are each independently preferably hydrogen or a hydrocarbon group having 1 to 12 carbons.

Moreover, Y is preferably a skeleton having a sufficient size from a viewpoint of hardness of a hardened film obtained, environmental resistance thereof and shielding properties thereof against the acidic solution. An equivalent is preferably approximately 200 or more, further preferably, approximately 250 or more in conversion into the equivalent of the epoxy group. Moreover, n is preferably 1 or more from a similar viewpoint. The number of the epoxy groups in one molecule is preferably 2 or more.

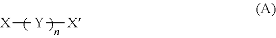

As the epoxy resin represented by formula (A), in view of satisfactory characteristics of the hardened film obtained and ease of handling of the compound, the compound is preferably an epoxy resin obtained by allowing epihalohydrin to react with an addition polymerization compound between dicyclopentadiene and phenols. As the phenols, phenol, cresol, tertiarybutylphenol, isobutylphenol, octylphenol or the like can be used. Among types of the epoxy resins, an epoxy resin represented by formula (I-a) is most preferred from a viewpoint of ease of manufacture, hardness of the hardened film obtained, environmental resistance thereof, and shielding properties thereof against the acidic solution. R₁ in the formula is each independently hydrogen or a hydrocarbon group having 1 to 12 carbons, preferably, each independently hydrogen or a hydrocarbon having 1 to 4 carbons, further preferably, hydrogen. Moreover, n is an integer from 1 to 11, preferably, 2 to 10 to represent a repeating unit.

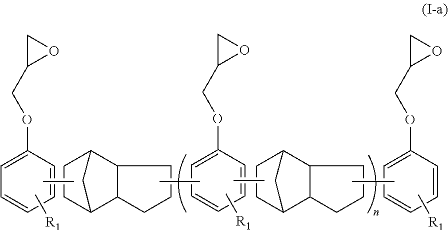

Specific examples of commercial products that can be used as the first component include EP-4088S (trade name) (ADEKA Corporation), HP-7200, HP-7200H, HP-7200L and HP-7200HH (trade names) (DIC, Inc.), and XD-1000, XD-1000-L and XD-1000-2L (trade names) (Nippon Kayaku Co., Ltd.). Among types of the products, HP-7200HH is most preferred from a viewpoint of ease of availability, lowness of cost, ease of preparation of the composition, ease of handling, hardness of the hardened film obtained, environmental resistance thereof, shielding properties thereof against the acidic solution, and so forth.

### 1-2. Second Component

A second component contained in the photosensitive composition of the invention is a compound including a (meth)acryl group in a molecule. “(Meth)acryl group” herein is used in generically meaning an acryl group and a methacryl group corresponding thereto. “(Meth)acrylate” herein is used in generically meaning an acrylate and a methacrylate corresponding thereto.

In the second component, the (meth)acryl group causes a cross-linking reaction and is polymerized during exposure in a coating prepared using the photosensitive composition of the invention. Thus, a difference in physical properties such as solubility in a developer arises between an exposed region and an unexposed region. Therefore, pattern formation is allowed on the coating by using the difference. The (meth)acryl group of the second component does not need to wholly react, but only needs to partially react.

The compound that can be used as the second component includes the (meth)acryl group in the molecule. From a viewpoint of reactivity and patterning characteristics, the number of the (meth)acryl groups in the molecule is preferably 2 or more, further preferably, 3 or more, most preferably, 4 or more.

Specific compounds that can be used as the second component include monofunctional (meth)acrylate such as methyl(meth)acrylate, ethyl(meth)acrylate, butyl(meth)acrylate, 2-ethylhexyl(meth)acrylate, phenyl(meth)acrylate, 2-hydroxypropyl(meth)acrylate, 3-hydroxypropyl(meth)acrylate, phthalic acid monohydroxyethyl(meth)acrylate, 2-hydroxy-3-phenoxypropyl(meth)acrylate, dicyclopentenyl(meth)acrylate, and 2,2,6,6-tetramethylpiperidinyl(meth)acrylate, and multifunctional (meth)acrylate such as 1,6-hexanediol di(meth)acrylate, ethylene glycol di(meth)acrylate, neopentyl glycol di(meth)acrylate, polyethylene glycol di(meth)acrylate, hydroxy pivalic acid neopentyl glycol di(meth)acrylate, trimethylolpropane tri(meth)acrylate, pentaerythritol di(meth)acrylate, dipentaerythritol penta(meth)acrylate, dicyclopentanyl di(meth)acrylate, ethoxylated hydrogenated bisphenol A di(meth)acrylate, ethoxylated bisphenol A di(meth)acrylate, ethoxylated bisphenol F di(meth)acrylate, ethoxylated bisphenol S di(meth)acrylate, ethoxylated isocyanuric acid diacrylate, ethoxylated isocyanuric acid triacrylate, hydroxypropyl di(meth)acrylate, diethylene glycol bis-hydroxypropyl(meth)acrylate, pentaerythritol tri(meth)acrylate and pentaerythritol tetra(meth)acrylate. Among types of the compounds, from a viewpoint of reactivity and patterning characteristics, pentaerythritol tri(meth)acrylate and pentaerythritol tetra(meth)acrylate are preferred, and pentaerythritol tetra(meth)acrylate are particularly preferred.

Specific examples of commercial products that can be preferably used as the second component include ARONIX M-101A, M-102, M-111, M-113, M-120, M-208, M-211B, M-305, M-306, M-450 and M-451 (trade names) (Toagosei Co., Ltd.), and A-9300 (trade name) (Shin-Nakamura Chemical Co., Ltd.).

### 1-3. Third Component

The third component contained in the photosensitive composition of the invention is an alkali-soluble polymer. “Alkali-soluble polymer” means a polymer having solubility in an alkali with such a degree that, when a film having a thickness in the range of 0.01 to 100 micrometers as formed using a composition containing 0.1 to 10% by weight of the polymer is dipped, for example, into an aqueous solution of 2.38% by weight of tetramethylammonium hydroxide at approximately 25° C. for 5 minutes, and then rinsed with pure water, the film does not remain.

The third component improves solubility in an alkaline developer, and contributes to improvement of patternability in the coating prepared using the photosensitive composition of the invention. Moreover, the third component contributes to improvement of hardness of the hardened film obtained, environmental resistance thereof, and shielding properties thereof against the acidic solution.

Specific examples of the alkali-soluble polymer that can be used for the third component include a polymer having an acidic group. The acidic groups improve solubility in the alkaline developer, and contribute to improvement of patternability. Moreover, the acidic group, and the reactive cyclic ether group of the first component of the photosensitive composition according to the invention cause a cross-linking reaction during calcination to form a three-dimensional network with a high density. Therefore, hardness of the hardened film obtained, environmental resistance thereof and shielding properties thereof against the acidic solution can be improved.

The acidic group may be any of generally known acidic groups such as a carboxyl group, a phenolic hydroxyl group, a sulfonate group and a phosphate group, but is preferably a carboxyl group from a viewpoint of lowness of manufacturing cost, and ease of a molecular design. Moreover, the number of the acidic groups may be 1 or 2 or more, and types are not necessarily only one, and may include a plurality thereof.

Such a polymer having the carboxyl group is obtained by copolymerizing a mixture of a radically polymerizable monomer having a carboxyl group, and a radically polymerizable monomer including no carboxyl group, for example. When such a polymer is used as the third component, solubility of the protective film obtained in the developer, hardness of the protective film, heat resistance thereof, and so forth can be easily controlled by suitably selecting types of radically polymerizable monomers, appropriately adjusting a mixing ratio thereof and synthesizing the polymer. For example, the solubility of the protective film in the developer can be easily adjusted by changing a mixing ratio of the radically polymerizable monomer including no carboxyl group and the radically polymerizable monomer having the carboxyl group. Moreover, hardness of the protective film, heat resistance thereof and so forth can be adjusted, and various functions can be provided by selecting a plurality of radically polymerizable monomers having no carboxyl group, suitably adjusting types and a mixing ratio thereof, and polymerizing the monomers with the radically polymerizable monomer having the carboxyl group.

The radically polymerizable monomer is a compound having a radically polymerizable functional group. Specific examples of the radically polymerizable functional groups include vinyl, vinylene, vinylidene, (meth)acryloyl and styryl. In the radically polymerizable monomer, it is feasible at least one radically polymerizable functional group is included in one molecule. Two or more functional groups may be included, but one functional group is preferred from a viewpoint of ease of a molecular design, ease of controlling characteristics, and ease of synthesis.

The radically polymerizable monomer including the carboxyl group is not particularly limited, if the monomer is a compound having the carboxyl group and the radically polymerizable functional group. In the radically polymerizable monomer including the carboxyl group, it is feasible at least one carboxyl group is included in one molecule.

The radically polymerizable monomer including the carboxyl group is preferably unsaturated monocarboxylic acid having 3 to 20 carbons, unsaturated dicarboxylic acid having 3 to 20 carbons, or a derivative of unsaturated carboxylic acid such as a monoester thereof. Specific examples of the radically polymerizable monomers having the carboxyl group include (meth)acrylic acid, crotonic acid, α-chloroacrylic acid, cinnamic acid, maleic acid, fumaric acid, itaconic acid, citraconic acid, mesaconic acid, ω-carboxypolycaprolactone mono(meth)acrylate, succinic acid mono[2-(meth)acryloyloxyethyl], maleic acid mono[2-(meth)acryloyloxyethyl] or cyclohexene-3,4-dicarboxylic acid mono[2-(meth)acryloyloxyethyl]. Among types of the monomers, from a viewpoint of hardness, patternability and environmental resistance, (meth)acrylic acid, itaconic acid or succinic acid mono(2-acryloyloxyethyl) is preferred, and (meth)acrylic acid is particularly preferred. The radically polymerizable monomer including the carboxyl group can be used alone or in combination with two or more kinds.

Specific examples of the radically polymerizable monomer including no carboxyl group include styrene, methylstyrene, vinyltoluene, chloromethylstyrene, (meth)acrylamide, methyl(meth)acrylate, butyl(meth)acrylate, a polystyrene macromonomer, a polymethylmethacrylate macromonomer, N-acryloyl morpholine, indene, methoxypolyethyleneglycol methacrylate, N-substituted maleimide and a radically polymerizable monomer having a ring structure. Among types of the monomers, N-substituted maleimide or a radically polymerizable monomer having a ring structure is particularly preferably used.

### N-Substituted Maleimide

N-substituted maleimide is a compound in which hydrogen bonded with nitrogen of maleimide is replaced by a hydrocarbon group having 1 to 20 carbons. Specific examples of the hydrocarbon groups include straight-chain or branched-chain alkyl having 1 to 20 carbons, cycloalkyl or cycloalkenyl that has 3 to 20 carbons and may have a substituent, and aryl that has 6 to 20 carbons and may have a substituent. A polymer prepared by polymerizing a mixture containing N-substituted maleimide has an imide structure, and therefore can improve heat resistance of the hardened film obtained, and contributes to improvement of environmental resistance thereof. N-substituted maleimide can be used alone or in combination with two or more kinds. Specific examples of N-substituted maleimide include N-methylmaleimide, N-ethylmaleimide, N-phenylmaleimide or N-cyclohexylmaleimide. Among types of the N-substituted maleimides, if N-cyclohexylmaleimide is used, heat resistance of the hardened film obtained is improved. Therefore, N-cyclohexylmaleimide is most preferred from a viewpoint of environmental resistance.

### Radically Polymerizable Monomer Having the Ring Structure

It is feasible the radically polymerizable monomer having the ring structure has only one ring. The ring structure provides the third component with rigidity and a steric structure. Therefore, hardness of the protective film obtained, environmental resistance thereof, and shielding properties thereof against the acidic solution are improved. Specific examples of such a radically polymerizable monomer having the ring structure include tricyclo[5.2.1.0^{2,6}]decanyl(meth)acrylate, dicyclopentanyl(meth)acrylate, dicyclopentenyloxyethyl(meth)acrylate, benzyl(meth)acrylate, isobornyl(meth)acrylate, cyclohexyl(meth)acrylate or phenyl(meth)acrylate. Use of dicyclopentayl(meth)acrylate is most preferred because environmental resistance of the protective film obtained and shielding properties thereof against the acidic solution are high.

### Any Other Radically Polymerizable Monomer Including No Carboxyl Group

If the third component is a copolymer prepared by copolymerizing a mixture containing any other radically polymerizable monomer including no carboxyl group in addition to the radically polymerizable monomer described above, the third component is preferred from a viewpoint of capability of suitably adjusting solubility in the developer and improving adhesion with a substrate, and environmental resistance. Any other radically polymerizable monomer may be used in one kind or two or more kinds. Specific examples of such a compound include styrene, methylstyrene, vinyltoluene, chloromethylstyrene, (meth)acrylamide, methyl(meth)acrylate, butyl(meth)acrylate, a polystyrene macromonomer, a polymethylmethacrylate macromonomer, N-acryloyl morpholine, indene, or (meth)acrylate having hydroxy. Among types of the compounds, (meth)acrylate having hydroxy is preferably used from a viewpoint of adhesion with the substrate and adjustment of solubility in the developer. It is feasible (Meth)acrylate having hydroxy has only one hydroxy. Specific examples of such (meth)acrylate having hydroxy include 2-hydroxyethyl(meth)acrylate, 2-hydroxypropyl(meth)acrylate, 4-hydroxybutyl(meth)acrylate, 1,4-cyclohexane dimethanol mono(meth)acrylate, glycerol mono(meth)acrylate and methoxypolyethyleneglycol(meth)acrylate. Among types of the compounds, methoxypolyethyleneglycol(meth)acrylate is most preferred from a viewpoint of adhesion with the substrate, and solubility in the developer.

The third component is preferably a polymer prepared by copolymerizing a mixture of monomers suitably selected from the radically polymerizable monomers described above. More specifically, the third component is preferably a copolymer of a radically polymerizable monomer including a carboxyl group, N-substituted maleimide, a radically polymerizable monomer having a ring structure, and (meth)acrylate having hydroxy. The third component is further preferably a copolymer of (meth)acrylic acid, N-cyclohexyl maleimide, dicyclopentanyl(meth)acrylate and (meth)acrylate having hydroxy, most preferably, a copolymer of (meth)acrylic acid, N-cyclohexyl maleimide, dicyclopentanyl(meth)acrylate and methoxypolyethyleneglycol(meth)acrylate. Use of the copolymers as the third component is preferred because hardness of the hardened film obtained, environmental resistance thereof, and shielding properties thereof against the acidic solution are excellent.

The third component is preferably prepared by copolymerizing a mixture obtained by mixing the radically polymerizable monomers described above with a suitable compounding ratio. More specifically, the third component is preferably a copolymer obtained by allowing radical polymerization of a mixture containing N-substituted maleimide in the range of approximately 10 to approximately 60% by weight, a radically polymerizable monomer including a carboxyl group in the range of approximately 2 to approximately 50% by weight, a radically polymerizable monomer having a ring structure in the range of approximately 20 to approximately 70% by weight, and any other radically polymerizable monomer in the range of approximately 0.1 to approximately 15% by weight. Such a copolymer is preferred because patternability, hardness and environmental resistance are all satisfactory. In particular, such a copolymer is further preferred as obtained by allowing radical copolymerization of a mixture containing N-substituted maleimide in the range of approximately 20 to approximately 40% by weight, a radically polymerizable monomer including a carboxyl group in the range of approximately 20 to approximately 40% by weight, a radically polymerizable monomer having a ring structure in the range of approximately 30% by weight to approximately 60% by weight, and any other polymerizable monomer in the range of approximately 1 to approximately 10% by weight.

A method for synthesizing the third component is not particularly limited, but radical polymerization in a solution using a solvent is preferred. A polymerization temperature is not particularly limited, if a radical is sufficiently generated at the temperature from a polymerization initiator to be used, but is ordinarily in the range of approximately 50° C. to approximately 150° C. Polymerization time is not particularly limited either, but is ordinarily in the range of approximately 3 to approximately 24 hours.

The solvent used for a polymerization reaction of the third component preferably dissolves the radically polymerizable monomer and the third component to be produced. Specific examples include methanol, ethanol, 1-propanol, 2-propanol, acetone, 2-butanone, ethyl acetate, propyl acetate, tetrahydrofuran, acetonitrile, dioxane, toluene, xylene, cyclohexanone, ethylene glycol monoethyl ether, propylene glycol monomethyl ether, propylene glycol monomethyl ether acetate (hereinafter, occasionally abbreviated as PGMEA), dethylene glycol dimethyl ether, diethylene glycol methyl ethyl ether, methyl 3-methoxypropionate, ethyl 3-ethoxypropionate, N,N-dimethylformamide or N-methyl-2-pyrrolidone, and the solvent may be a mixture thereof.

As the polymerization initiator used upon synthesizing the third component, a compound generating a radical by heat, an azo-based initiator, such as 2,2′-azobis(2,4-dimethylvaleronitrile), and a peroxide-based initiator such as benzoyl peroxide can be used. In order to adjust a molecular weight of the third component obtained, a proper amount of chain-transferring agent such as thioglycolic acid may be added.

An acid value of the third component is preferably in the range of approximately 20 to approximately 400 mg KOH/g. The acid value in the range is preferred from a viewpoint of further optimizing a developing time until an unexposed part is dissolved with the developer. Furthermore, the acid value of the third component in the range of approximately 25 to approximately 200 mg KOH/g is further preferred from a viewpoint of optimization of the developing time, and suppression of film roughness during development. The acid value in the invention has been measured based on JIS K0070.

The third component having a weight average molecular weight in the range of approximately 2,000 to approximately 100,000 as determined according to GPC analysis using polystyrene as a standard is preferred from a viewpoint of prevention of a development residue and prevention of roughness on a film surface during development. Furthermore, the third component having the weight average molecular weight in the range of approximately 2,500 to approximately 50,000 is further preferred additionally from a viewpoint of optimizing the developing time until the unexposed part is dissolved with the developer.

In addition, “weight average molecular weight” herein means a standard polystyrene equivalent weight average molecular weight measured according to GPC. Herein, GPC measurement is carried out by using polystyrene having a weight average molecular weight in the range of 645 to 132,900 (trade name: Polystyrene Calibration Kit PL2010-0102, for example) (VARIAN, Inc.) for a standard polystyrene, PLgelMIXED-D (trade name) (VARIAN, Inc.) for a column, and THF as a mobile phase, and under conditions of a column temperature of 35° C. and a flow rate of 1 ml/min.

### 1-4. Solvent

Specific examples of solvents used as a constituent of the photosensitive composition according to the invention include water, butyl acetate, butyl propionate, ethyl lactate, methyl oxyacetate, ethyl oxyacetate, butyl oxyacetate, methyl methoxyacetate, ethyl methoxacetate, butyl methoxyacetate, methyl ethoxyacetate, ethyl ethoxyacetate, methyl 3-oxypropionate, ethyl 3-oxypropionate, methyl 3-methoxypropionate, ethyl 3-methoxypropionate, methyl 3-ethoxypropionate, ethyl 3-ethoxypropionate, methyl 2-hydroxypropionate, ethyl 2-hydroxypropionate, propyl 2-hydroxypropionate, methyl 2-methoxypropionate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate, ethyl 2-ethoxy-2-methylpropionate, methyl pyruvate, ethyl pyruvate, propyl pyruvate, methyl acetoacetate, ethyl acetoacetate, methyl 2-oxobutanate, ethyl 2-oxobutanate, dioxane, ethylene glycol, diethylene glycol, triethylene glycol, propylene glycol, dipropylene glycol, tripropylene glycol, 1,4-butanediol, ethylene glycol monoisopropyl ether, ethylene glycol monobutyl ether, propylene glycol monomethyl ether, propylene glycol monomethyl ether acetate (hereinafter, occasionally abbreviated as PGMEA), propylene glycol monoethyl ether acetate, propylene glycol monopropylether acetate, dipropylene glycol monoethyl ether acetate, dipropylene glycol monobutyl ether acetate, ethylene glycol monobutyl ether acetate, cyclohexanone, cyclopentanone, diethylene glycol monomethyl ether, diethylene glycol monomethyl ether acetate, diethylene glycol monoethyl ether, diethylene glycol monoethyl ether acetate, diethylene glycol monobutyl ether, diethylene glycol monobutyl ether acetate, diethylene glycol dimethyl ether, diethylene glycol diethyl ether, diethylene glycol methyl ethyl ether, toluene, xylene, anisole, γ-butyrolactone, N,N-dimethylacetamide, N-methyl-2-pyrrolidone or dimethylimidazolidinone. The solvents may be used in one kind of compound, or a mixture of two or more kinds of compounds.

### 1-5. Photopolymerization Initiator

The photosensitive composition of the invention may also contain various kinds of photopolymerization initiators. The photopolymerization initiators are a compound that generates a radical by light to have an effect on accelerating hardening of the second component by irradiation with light. Having a phosphorous atom in the molecule is preferred because heat resistance of the hardened film obtained is high.

Specific examples of the photopolymerization initiators used in the invention include benzophenone, Michler's ketone, 4,4′-bis(diethylamino)benzophenone, xanthone, thioxanthone, isopropyl xanthone, 2,4-diethylthioxanthone, 2-ethylanthraquinone, acetophenone, 2-hydroxy-2-methylpropiophenone, 2-hydroxy-2-methyl-4′-isopropylpropiophenone, 1-hydroxycyclohexyl phenyl ketone, isopropyl benzoin ether, isobutyl benzoin ether, 2,2-diethoxyacetophenone, 2,2-dimethoxy-2-phenylacetophenone, camphorquinone, benzanthrone, 2-methyl-1-[4-(methylthio)phenyl]-2-morpholinopropan-1-one, 2-benzyl-2-dimethylamino-1-(4-morpholinophenyl)-butanone-1,ethyl 4-dimethylaminobenzoate, isoamyl 4-dimethylaminobenzoate, 4,4′-di(t-butylperoxycarbonyl)benzophenone, 3,4,4′-tri(t-butylperoxycarbonyl)benzophenone, 2,4,6-trimethylbenzoyldiphenyl phosphine oxide, 2-(4′-methoxystyryl)-4,6-bis(trichloromethyl)-s-triazine, 2-(3′,4′-dimethoxystyryl)-4,6-bis(trichloromethyl)-s-triazine, 2-(2′,4′-dimethoxystyryl)-4,6-bis(trichloromethyl)-s-triazine, 2-(2′-methoxystyryl)-4,6-bis(trichloromethyl)-s-triazine, 2-(4′-pentyloxystyryl)-4,6-bis(trichloromethyl)-s-triazine, 4-[p-N,N-di(ethoxycarbonylmethyl)]-2,6-di(trichloromethyl)-s-triazine, 1,3-bis(trichloromethyl-5-(2′-chlorophenyl)-s-triazine, 1,3-bis(trichloromethyl-5-(4′-methoxyphenyl)-s-triazine, 2-(p-dimethylaminostyryl)benzoxazole, 2-(p-dimethylaminostyryl)benzthiazole, 2-mercaptobenzothiazole, 3,3′-carbonyl bis(7-diethylaminocoumarin), 2-(o-chlorophenyl)-4,4′,5,5′-tetraphenyl-1,2′-biimidazole, 2,2′-bis(2-chlorophenyl)-4,4′,5,5′-tetrakis(4-ethoxycarbonylphenyl)-1,2′-biimidazole, 2,2′-bis(2,4-dichlorophenyl)-4,4′,5,5′-tetraphenyl-1,2′-biimidazole, 2,2′-bis(2,4-dibromophenyl)-4,4′,5,5′-tetraphenyl-1,2′-biimidazole, 2,2′-bis(2,4,6-trichlorophenyl)-4,4′,5,5′-tetraphenyl-1,2′-biimidazole, 3-(2-methyl-2-dimethylaminopropionyl)carbazole, 3,6-bis(2-methyl-2-morpholinopropionyl)-9-n-dodecylcarbazole, 1-hydroxycyclohexyl phenyl ketone, bis(η5-2,4-cyclopentadiene-1-yl)-bis(2,6-difluoro-3-(1H-pyrrole-1-yl)-phenyl titanium, 3,3′,4,4′-tetra(t-butylperoxycarbonyl)benzophenone, 3,3′,4,4′-tetra(t-hexylperoxycarbonyl)benzophenone, 3,3′-di(methoxycarbonyl-4,4′-di(t-butylperoxycarbonyl)benzophenone, 3,4′-di(methoxycarbonyl-4,3′-di(t-butylperoxycarbonyl)benzophenone, 4,4′-di(methoxycarbonyl-3,3′-di(t-butylperoxycarbonyl)benzophenone, 2-(3-methyl-3H-benzothiazole-2-ylidene)-1-naphthalene-2-yl-ethanone, or 2-(3-methyl-1,3-benzothiazole-2(3H)-ylidene)-1-(2-benzoyl)ethanone and 1,2-octanedione-1-[4-(phenylthiophenyl)-2-(O-benzoyloxime). The compounds may be used alone, and also effectively used in a mixture of two or more kinds.

Among types of the initiators, from a viewpoint of enhancing sensitivity of the photosensitive composition of the invention, the photopolymerization initiator preferably includes one or more kinds selected from 2,4,6-trimethylbenzoyldiphenyl phosphine oxide, 2-methyl-1-[4-(methylthio)phenyl]-2-morpholinopropane-1-one, 2-benzyl-2-dimethylamino-1-(4-morpholinophenyl)-butanone-1,2-(dimethylamino)-2-[(4-methylphenyl)methyl]-1-[4-(4-morpholinyl)phenyl]-1-butanone, 3,3′-di(methoxycarbonyl-4,4′-di(t-butylperoxycarbonyl)benzophenone, 3,4′-di(methoxycarbonyl-4,3′-di(t-butylperoxycarbonyl)benzophenone, 4,4′-di(methoxycarbonyl-3,3′-di(t-butylperoxycarbonyl)benzophenone, 4,4′-bis(diethylamino)benzophenone, 2-(3-methyl-3H-benzothiazole-2-ylidene)-1-naphthalene-2-yl-ethanone, and 2-(3-methyl-1,3-benzothiazole-2(3H)-ylidene)-1-(2-benzoyl)ethanone and 1,2-octanedione-1-[4-(phenylthiophenyl)-2-(O-benzoyloxime)].

As a commercial product, Irgacure 907, Irgacure 369, Irgacure 379 or Irgacure OXE01 (trade names) (BASF Japan Ltd.), or the like can be preferably used.

### 1.6 Arbitrary Component

The photosensitive composition of the invention may also contain any other monomer, polymer or copolymer in order to further improve various characteristics. Moreover, the photosensitive composition may also contain a surfactant, an adhesion accelerator, a corrosion inhibitor and a polymerization inhibitor, when necessary.

### 1-6-1. Surfactant

The photosensitive composition of the invention may contain the surfactant for improving wettability to a base substrate or uniformity of a surface of the hardened film, for example. As the surfactant, a silicone surfactant, an acrylic surfactant, a fluorinated surfactant and so forth are used.

Specific examples of commercial products of the surfactants include a silicone surfactant such as Byk-300, Byk-306, Byk-335, Byk-310, Byk-341, Byk-344 and Byk-370 (trade names) (BYK-Chemie Japan K. K.), a silicone surfactant such as KP-341 (trade name) (Shin-Etsu Chemical Co., Ltd.), an acrylic surfactant such as ByK-354, ByK-358 and ByK-361 (trade names) (BYK-Chemie Japan K.K.), and a fluorinated surfactant such as DFX-18, Futargent 250 or Futargent 251 (trade name) (Neos Co., Ltd.), and Megafac F-479 (trade name) (DIC, Inc.).

The surfactant used in the invention may be used in one kind of compound or a mixture of two or more kinds of compounds.

Content of the surfactant is preferably in the range of approximately 0.001 to approximately 1% by weight based on solid content in the photosensitive compound because uniformity of the hardened film is improved. If a balance with other characteristics is taken into consideration, the content is further preferably in the range of approximately 0.001 to approximately 0.5% by weight.

### 1-6-2. Adhesion Accelerator

The photosensitive composition of the invention may further contain various kinds of adhesion accelerators.

As the adhesion accelerator, a compound for forming a bond between a substrate and a component in the composition, a compound having a functional group showing affinity between the substrate and the component in the composition, or the like is known. Moreover, adhesion may be accelerated by a different adhesion accelerator based on a different mechanism. Specific examples of the adhesion accelerators include a silane coupling agent such as 3-(3-aminopropyl)triethoxysilane, 3-(3-mercaptopropyl)trimethoxysilane, 3-methacryloyloxy propyltrimethoxysilane and 3-glycidoxypropyltrimetoxysilane, but the adhesion accelerators are not limited thereto. Moreover, the adhesion accelerator may be used in one kind or in combination with two or more kinds.

### 1-6-3. Corrosion Inhibitor

The photosensitive composition of the invention may further contain various kinds of corrosion inhibitors. A publicly known corrosion inhibitor such as a hindered amine compound and a hindered phenol compound can be used. Moreover, the corrosion inhibitor may be used in one kind or in combination with two or more kinds. Specific examples of commercial products include Irgafos XP40, Irgafos XP60, Irganox 1010, Irganox 1035, Irganox 1076, Irganox 1135 and Irganox 1520L (trade names) (BASF Japan Ltd.).

### 1-6-4. Polymerization Inhibitor

The photosensitive composition of the invention may further contain various kinds of polymerization inhibitors. A publicly known polymerization inhibitor such hydroquinones, phenols and quinones can be used. Moreover, the polymerization inhibitor may be used in one kind or in combination with two or more kinds. Specific examples of the polymerization inhibitors include hydroquinone monomethyl ether, 4-methoxyphenol, hydroquinone or naphthoquinone.

### 2. Composition of the Photosensitive Composition

As the content of each component in a coating forming composition of the invention, from a viewpoint of a satisfactory dispersibility of each component in the composition, a high hardness of a coating obtained from the composition of the invention, environmental resistance thereof and patternability thereof, the first component is preferably in the range of approximately 1 to approximately 10% by weight, the second component is preferably in the range of approximately 1 to approximately 10% by weight, the third component is preferably in the range of approximately 1 to approximately 10% by weight, and the fourth component is preferably in the range of approximately 70 to approximately 97% by weight, based on the total amount of the photosensitive composition.

The first component is further preferably in the range of approximately 1 to approximately 6% by weight, the second component is further preferably in the range of approximately 3 to approximately 9% by weight, the third component is further preferably in the range of approximately 3 to approximately 9% by weight, and the fourth component is further preferably in the range of approximately 76 to approximately 93% by weight, based on the total amount of the photosensitive composition.

The coating forming composition of the invention can be manufactured by suitably selecting the components described above and suitably selecting processes of agitation, mixing, heating, cooling, dissolving, dispersing of the components, or the like according to a known method.

### 3. Patterning Method Using the Photosensitive Composition

A method for forming the protective film on the transparent conductive film including the nanostructure by using the photosensitive composition manufactured as described above, and a method for patterning the protective film and the transparent conductive film will be explained below.

“Transparent conductive film” of the invention means a film having a surface resistance of approximately 10⁴Ω/□ or less and having a total luminous transmittance of approximately 80% or more. As the transparent conductive film, any film may be used, if the film has transparency and conductivity. However, from a viewpoint of conductivity, optical characteristics, manufacturing cost, flexibility, and no need of a high temperature during film formation, the film includes the nanostructure.

“Nanostructure” of the invention means a structure that satisfies conditions that (1) at least one element of a shape dimension is approximately 1 micrometer or less, (2) the nanostructure has a distinct regularity in the shape, and (3) the nanostructure is a single compound or an aggregate, and has conductivity. As for the shape dimension, at least one element, such as length and thickness, may be approximately 1 micrometer or less. For example, in a case of a cylindrical structure having a diameter of approximately 1 micrometer or less, the length may be approximately 1 micrometer or more.

“Nanowires” of the invention means the nanostructure and a conductive material having a wire shape or a tubular shape. The nanowires may have a linear shape or a gently or steeply bent shape. In a case of the tubular shape, the nanowires may be porous or nonporous. The nanowires may be flexible or rigid. Specific examples of types of elements contained in the nanowires include at least one type selected from the group of gold, silver, platinum, copper, nickel, iron, cobalt, zinc, ruthenium, rhodium, palladium, cadmium, osmium and iridium, and an alloy formed by combining the metals. From a viewpoint for obtaining a coating having a low surface resistance and a high total luminous transmittance, the nanowires preferably contain at least one type from any one of gold, silver and copper. The metals have a high conductivity, and therefore density of the metal on a surface can be reduced upon obtaining a desired surface resistance. Therefore, a high transmittance can be realized. Among types of the metals, the nanowires further preferably contain at least one type of gold or silver. As one aspect of preferred embodiments, the nanowires preferably contain silver. The nanowires have a fixed distribution in length thereof in a minor axis, length thereof in a major axis, and an aspect ratio thereof. The distribution is selected from a viewpoint of forming a coating having a high total luminous transmittance and a low surface resistance as the coating obtained from the composition of the invention. Specifically, a mean of length of the first component in the minor axis is preferably in the range of approximately 1 nanometer to approximately 500 nanometers, further preferably, in the range of approximately 5 nanometers to approximately 200 nanometers, still further preferably, in the range of approximately 5 nanometers to approximately 100 nanometers, particularly preferably, in the range of approximately 10 nanometers to approximately 100 nanometers. Moreover, a mean of length of the first component in the major axis is preferably in the range of approximately 1 micrometer to approximately 100 micrometers, further preferably, in the range of approximately 1 micrometer to approximately 50 micrometers, still further preferably, in the range of approximately 2 micrometers to approximately 50 micrometers, particularly preferably, in the range of approximately 5 micrometers to approximately 30 micrometers. As for the first component, the mean of length in the minor axis and the mean of length in the major axis preferably satisfy the range described above, and simultaneously a mean of the aspect ratio is preferably larger than approximately 1, further preferably, approximately 10 or more, still further preferably, approximately 100 or more, particularly preferably, approximately 200 or more. Herein, “aspect ratio” is expressed in terms of a value determined from an equation: a/b, when an average length of the first component in the minor axis is approximated as “b,” and an average length of the first component in the major axis is approximated as “a.” Then, “a” and “b” can be measured using a scanning electron microscope.

The transparent conductive film may be formed on at least one side on the substrate such as a glass substrate. Hereinafter, the substrate on which such a transparent conductive film is formed is abbreviated as “transparent conductive film substrate.” The substrate may be stiff or flexible. Alternatively, the substrate may be colored. Specific examples of materials of the substrate include glass, polyimide, polycarbonate, polyethersulfone, acryloyl, polyester, polyethylene terephthalate, polyethylene naphthalate, polyolefin and polyvinyl chloride. The materials preferably have a high luminous transmittance and a low haze value. On the substrate, a circuit such as a TFT device may be formed, and an organic functional material such as a color filter and an overcoat and an inorganic functional material such as a silicon nitride film or a silicon oxide film may be formed. Moreover, a plurality of layers may be laminated on the substrate.

Although the surface resistance of the transparent conductive film including the nanostructure is determined depending on an application, a transparent conductive film having a surface resistance in the range of approximately 10Ω/□ to approximately 1,000Ω/□ are used in many cases. The surface resistance is determined by a film thickness, and an area density of the nanostructure. From a viewpoint of a low surface resistance, a larger film thickness is preferred, and from a viewpoint of the optical characteristics, a smaller film thickness is preferred. Thus, when preferred embodiments are comprehensively taken into account, the film thickness is preferably in the range of approximately 5 nanometers to approximately 500 nanometers, further preferably, in the range of approximately 5 nanometers to approximately 200 nanometers, still further preferably, in the range of approximately 5 nanometers to approximately 100 nanometers.

In the invention, unless otherwise noted, the surface resistance is expressed in terms of a measured value according to a non-contact measurement method as described later.

In the following, a case of using the transparent conductive film substrate is taken for example, and a detail will be explained for the method for forming the protective film on the transparent conductive film including the nanostructure using the photosensitive composition of the invention, and the method for patterning the protective film and the transparent conductive film.

Process 1 for Applying the Photosensitive Composition of the Invention onto the Transparent Conductive Film Substrate

First, the photosensitive composition of the invention is applied onto the transparent conductive film substrate including the nanostructure. As an application method, a general method can be applied, such as a spin coating method, a slit coating method, a dip coating method, a blade coating method, a spray method, a relief printing method, an intaglio printing method, a planographic printing method, a dispensing method and an inkjet method. From a viewpoint of uniformity of the film thickness, and productivity, the spin coating method and the slit coating method are preferred, and the slit coating method is further preferred.

### Process 2 for Drying the Photosensitive Composition

Next, the substrate is dried on a hot plate or in an oven, and the solvent is removed. Removal of the solvent is carried out by performing heat treatment of a coated article, when necessary. Although drying conditions are different depending on types of solvents, drying is ordinarily carried out at a temperature in the range of approximately 60° C. to approximately 120° C. for approximately 1 to approximately 5 minutes.

Process 3 for Irradiating the Photosensitive Composition with Light Through a Photomask

Subsequently, the substrate is irradiated with radiation such as ultraviolet light through a mask having a desired pattern shape. Although irradiation conditions depend on types of compositions, intensity in the range of approximately 5 to approximately 1,000 mJ/cm² is suitable in i-rays, for example.

### Process 4 for Developing the Photosensitive Composition Using the Developer

In a case where the substrate is irradiated with ultraviolet light through the mask, the second component is polymerized in a part where ultraviolet light is irradiated to form a three-dimensionally cross-linked body, and to be insolubilized in the developer. Therefore, if a substrate after irradiation with ultraviolet light is treated with the developer, a part where ultraviolet light is not irradiated can be removed from the substrate, and the photosensitive composition is developed. More specifically, the substrate is dipped into the developer according to a method ordinarily applied in development of the organic film, such as shower development, spray development, paddle development and dip development, and an unwanted part is dissolved and removed.

Specific examples of the developers include an alkaline aqueous solution of inorganic alkalis such as sodium carbonate, sodium hydrogencarbonate, potassium carbonate, potassium hydrogencarbonate, sodium hydroxide and potassium hydroxide, and organic alkalis such as tetramethylammonium hydroxide and tetraethylammonium hydroxide. Moreover, a suitable amount of methanol, ethanol, a surfactant or the like can also be added to the developer and used. For example, the surfactant may be added to the developer for the purpose of reducing the development residue or optimizing the pattern shape. The surfactant can be selected from an anionic, cationic or nonionic surfactant and used. In particular, addition of a nonionic polyoxyethylene alkyl ether is preferred because a satisfactory pattern shape is obtained.

### Process 5 for Allowing Thermosetting of the Photosensitive Composition

Subsequently, the substrate is calcinated on the hot plate or in the oven. Calcination causes a cross-linking reaction between the reactive cyclic ether groups included in the first component of the photosensitive composition according to the invention, between the acryl groups included in the second component thereof, or between the reactive cyclic ether group included in the first component and the acidic group included in the third component. Thus, a strong three-dimensionally cross-linked body is formed and hardness and environmental resistance of the coating are improved. In the cross-linking reaction, the groups in the composition do not need to wholly react, it is feasible partially react. A calcination temperature is ordinarily in the range of approximately 100° C. to approximately 250° C., although a calcination temperature is different depending on the composition. The calcination temperature is particularly preferably in the range of approximately 100° C. to approximately 160° C. from a viewpoint of surface conductivity of the substrate, transparency and environmental resistance of the film.

### Process 6 for Etching the Transparent Conductive Film Substrate Using the Acidic Solution

On the substrate, the protective film is formed on the transparent conductive film in a region where ultraviolet light is irradiated, and is not formed on the transparent conductive film in a region where ultraviolet light is not irradiated. Therefore, if the substrate is treated with the acidic solution, the transparent conductive film can be subjected to patterning. More specifically, the transparent conductive film in a region where the protective film is not formed is removed by the acidic solution, and the transparent conductive film in a region where the protective film is formed is not removed and remains owing to shielding properties of the protective film against the acidic solution. In particular, the protective film formed using the photosensitive composition of the invention has excellent shielding properties against the acidic solution. Therefore, a pattern of the transparent conductive film is formed with a high resolution in accordance with a pattern shape of the protective film. As an etching method, etching can be performed by dipping the substrate into the acidic solution according to a method ordinarily applied in development in the organic film, such as shower development, spray development, paddle development and dip development. As the acidic solution, any acidic solution can be used, if the acidic solution is generally used for an etching application. Such an acidic solution can be used as an aqueous solution of sulfuric acid-hydrogen peroxide, an aqueous solution of persulfate such as ammonium persulfate, sodium persulfate and potassium persulfate, an aqueous solution of ferric chloride, an aqueous solution of cupric chloride, hydrochloric acid, nitric acid, hot dilute sulfuric acid, an aqueous solution of iodic acid, a mixed solution of hydrochloric acid and nitric acid (royal water), an aqueous solution of oxalic acid, an aqueous solution of dodecylbenzenesulfonic acid-oxalic acid, an aqueous solution of hydrofluoric acid, an aqueous solution of ammonium fluoride and an aqueous solution of phosphoric acid. Among types of the acidic solutions, the aqueous solution of phosphoric acid or an aqueous solution of a mixture containing phosphoric acid is particularly preferred because patternability of the transparent conductive film substrate including the nanostructure is satisfactory.

In addition, orders of each process as described above may be suitably interchanged. For example, process 5 can be performed after process 1 to process 3, and then process 4 can also be performed. In the above case, hardening of the second component is accelerated in process 5. Therefore, the order described above may be suitable depending on conditions of the pattern shape or the types of developers. Moreover, a suitable treatment process, a washing process and a drying process may be suitably incorporated before or after any process. Specific examples of the treatment processes include plasma surface treatment, ultrasonic treatment, ozone treatment, washing treatment using a suitable solvent, and heat treatment. Moreover, a process for immersing the substrate in water may be incorporated.

Process 6 can be performed after process 4. For example, process 5 can be performed after process 1 to process 4, and then process 6 can be performed. Process 5 can be performed after process 1 to process 3, and then process 4 can be performed, and then process 6 can be further performed. Process 6 can be performed after process 1 to process 4, and then process 5 can also be performed.

The plasma surface treatment can be applied in order to enhance applicability to the coating forming composition or the developer. For example, the surface of the substrate or the coating forming composition can be treated by using oxygen plasma under conditions of 100 W, 90 seconds, an oxygen flow rate of 50 sccm (sccm; standard cc/min) and a pressure of 50 Pa. The ultrasonic treatment is applied by immersing the substrate into a solvent to propagate, for example, ultrasonic waves having a frequency of approximately 200 kHz. Thus, fine particles and so forth physically deposited on the substrate can be removed. The ozone treatment is applied by blowing air onto the substrate, and simultaneously irradiating the substrate with ultraviolet light. Thus, deposits and so forth on the substrate can be effectively removed by oxidizing power of ozone generated by ultraviolet light. The washing treatment is applied by spraying pure water in a mist form or shower form, for example. Thus, a particulate impurity can be washed away and removed by solubility and pressure. The heat treatment is a method for removing a compound intended to be removed on the substrate by volatilizing the compound. A heating temperature is suitably set up in consideration of a boiling point of the compound intended to be removed. For example, when the compound intended to be removed is water, heating is carried out in the range of approximately 50° C. to approximately 80° C.

As for the surface resistance and the total luminous transmittance of the transparent conductive film substrate having the protective film obtained according to the manufacturing method described above, when an application in the electronic device is taken into consideration, the surface resistance is preferably in the range of approximately 1Ω/□ to approximately 1,000Ω/□ and the total luminous transmittance is preferably approximately 80% or more, and the surface resistance is further preferably in the range of approximately 10Ω/□ to approximately 500Ω/□, and the total luminous transmittance is further preferably approximately 85% or more.

“Total luminous transmittance” herein means a ratio of transmitted light to incident light, and transmitted light includes a directly transmitted component and a scattered component. A light source is illuminant C and a spectrum is expressed in terms of CIE luminance function y.

If the protective film thickness is in the range of approximately 10 nanometers to approximately 10 micrometers, preferably, in the range of approximately 50 nanometers to approximately 5 micrometers, further preferably, in the range of approximately 500 nanometers to approximately 2 micrometers, a balance for patternability, hardness and environmental resistance is satisfactory.

According to the manufacturing method described above, the transparent conductive film substrate can be manufactured in which the region having the protective film on the transparent conductive film and the region having no protective film on the transparent conductive film exist in an identical substrate by performing process 1 to process 5 in the order, for example. Such a transparent conductive film substrate is advantageous because electrical contact can be easily established from a substrate surface in the region having no protective film on the transparent conductive film, and the transparent conductive film can be protected with the protective film in any other region.

According to the manufacturing method described above, the transparent conductive film substrate having the transparent conductive film that is subjected to patterning and protected with the protective film can be manufactured by performing process 1 to process 6 in the order, for example. As described later, such a transparent conductive film substrate can be preferably applied to a product such as the electronic device.

### 4. Application of the Protective Film Using the Photosensitive Composition

The transparent conductive film having the protective film (hereinafter, abbreviated as a transparent conductive film with the protective film or a transparent electrode with the protective film) as formed using the photosensitive composition of the invention is used for the electronic device in view of conductivity and optical characteristics thereof.

Specific examples of the electronic devices include a liquid crystal display device, an organic electroluminescence display, an electronic paper, a touch panel device and a photovoltaic cell device.

The electronic device may be prepared using a stiff substrate, a flexible substrate, and also a combination thereof. Moreover, the substrate used for the electronic device may be transparent or colored.

Examples of the transparent conductive film with the protective film used for the liquid crystal display device include a pixel electrode formed on a side of an array substrate of a thin film transistor (TFT) and a common electrode formed on a side of a color filter substrate. Specific examples of display modes of LCD include a twisted nematic (TN), multi vertical alignment (MVA), patterned vertical alignment (PVA), in plane switching (IPS), fringe field switching (FFS), polymer stabilized vertical alignment (PSA), optically compensated bend (OCB), continuous pinwheel alignment (CPA) or blue phase (BP) mode. Moreover, the display devices include a transmissive type, a reflective type and a transflective type for each of the modes. The pixel electrode of LCD is subjected to patterning for each pixel, and electrically connected with a drain electrode of TFT. In addition thereto, for example, the IPS mode has a comb electrode structure, and the PVA mode has a slit structure in the pixel.

The transparent conductive film with the protective film used for the organic electroluminescence display is ordinarily subjected to patterning in a stripe form on the substrate when the film is used as a conductive region according to a passive type driving mode. A direct current voltage is applied between a conductive region (anode) in a stripe form, and a conductive region (cathode) in a stripe form arranged orthogonally thereto to allow pixels to emit light in a matrix form and display an image. When the film is used as an electrode according to an active type driving mode, the film is subjected to patterning for each pixel on a side of a TFT array substrate.

The touch panel device includes a resistive type and a capacitive type depending on a detection method, and the transparent electrode with the protective film is used for any of types. The transparent electrode with the protective film used for the capacitive type is subjected to patterning.

The electronic paper includes a microcapsule type, a quick response liquid powder type, a liquid crystal type, an electrowetting type, an electrophoretic type and a chemical change type depending on a display method, and the transparent electrode with the protective film is used for any of types. The transparent electrode with the protective film is subjected to patterning in an arbitrary shape in any of types.

The photovoltaic cell device includes a silicon type, a compound type, an organic type and a quantum dot type depending on a material of an optical absorption layer, and the transparent electrode with the protective film is used for any of types. The transparent electrode with the protective film is subjected to patterning in an arbitrary shape in any of types.

It will be apparent to those skilled in the art that various modifications and variations can be made in the invention and specific examples provided herein without departing from the spirit or scope of the invention. Thus, it is intended that the invention covers the modifications and variations of this invention that come within the scope of any claims and their equivalents.

The following examples are for illustrative purposes only and are not intended, nor should they be interpreted to, limit the scope of the invention.

### EXAMPLES

In the following, the invention will be explained in greater detail by way of Examples, but the invention is in no way limited to the Examples. In Examples and Comparative Examples, ultrapure water was used as water being a constituent. However, ultrapure water may be referred to simply as water below. Ultrapure water was prepared using Puric FPC-0500-0M0 (trade name) (Organo Corporation).

Measurement methods or evaluation methods in each evaluation item were applied in the manner described below.

Unless otherwise noted, measurements (1) to (5) were carried out in an unetched region in which a transparent conductive film remained in samples to be evaluated.

### (1) Measurement of Surface Resistance

As the evaluation method, a non-contact type surface resistance measurement method using an eddy current was applied. Surface resistance (Ω/□) was measured using 717 B-H (DELCOM, Inc.). Volume resistivity (Ω·cm) and conductivity (Siemens/cm) can be determined from the thus obtained surface resistance value and thickness of a conductive film.

### (2) Measurement of Total Luminous Transmittance and Haze

Haze-Gard Plus (BYK Gardner, Inc.) was used for measurement of total luminous transmittance and haze. Air was used as a reference.

### (3) Testing of Environmental Resistance

Environmental resistance was evaluated by leaving a transparent conductive film to stand in a high temperature and high humidity oven at 70° C. and 90% RH, measuring total luminous transmittance and haze after 300 hours, and comparing a measured value with an initial value.

As evaluation results, when a rate of change of surface resistance, total luminous transmittance, and haze was in the range of 0% to 5%, as compared with the initial value, a sample was classified to be “satisfactory (excellent)”, when the rate was in the range of 6% to 10%, a sample was classified to be “fairly satisfactory (good),” when the rate was 11% to 50%, a sample was classified to be “somewhat poor (marginal),” and when the rate was higher than 51%, a sample was classified to be “poor (bad).”

### (4) Hardness

In measurement of hardness, testing was conducted using each type of pencils from 6B to 2H by using a tester in accordance with “Pencil scratch tester for a paint film (JIS K5401).” A film surface of the evaluation sample after testing was visually observed, and whether or not a coating was broken was evaluated.

In the evaluation, when the hardest pencil without causing break of the coating was 2H or higher, a sample was classified to be “satisfactory (excellent),” when such a pencil was lower than 2H and 6B or higher was classified to be “somewhat poor (marginal),” and when flaking was caused with all pencils, a sample was classified to be “poor (bad).”

### (5) Film Thickness

Profilometer P-16+ (trade name) (KLA-Tencor Corporation) was used for measurement of film thickness. Specifically, a coating on a substrate was irradiated with an irradiation energy of 1000 mJ/cm² (low pressure mercury lamp (254 nanometers)), and a hardened film of a composition as a measurement object was formed on a glass plate including a substrate surface subjected to UV ozone treatment in a manner similar to each Example and under conditions similar thereto. Then, part of film was shaved off, and a profile on a boundary surface was measured. A measured value of the profile was described as a film thickness of an object sample in each Example. In addition, the film thickness was measured in accordance with “Test method for thickness of fine ceramic thin films—Film thickness by contact probe profilometer (JIS R1636).”

### (6) Evaluation of Patternability of a Protective Film

A pattern shape of a protective film was observed using an incident-light darkfield microscope having a magnification of 500 times. When a sample was satisfactorily subjected to patterning without chipping or flaking of patterns, the sample was classified to be “satisfactory (excellent),” a sample with chipping or flaking of patterns was classified to be “somewhat poor (marginal),” and a sample with no pattern formation was classified to be “poor (bad).”

### (7) Evaluation of Patternability of a Transparent Conductive Film

A pattern shape of a transparent conductive film was observed using an incident-light darkfield microscope having a magnification of 500 times. Dimensions of respective pattern shapes of the protective film and the transparent conductive film were compared. In a case where a deviation of dimensions between both films was less than 5%, a sample of the transparent conductive film was classified to be “satisfactory (excellent),” in a case where the deviation was 5% or more and less than 10%, a sample thereof was classified to be “fairly satisfactory (good),” and in a case where the deviation was 10% or more or no pattern was formed, a sample thereof was classified to be “poor (bad).”

A composition for forming the transparent conductive film and a substrate on which the transparent conductive film was formed (hereinafter, referred to as a transparent conductive film substrate) that were used in Examples and Comparative Examples were prepared based on the description disclosed in JP 2010-507199 A.

### Synthesis of Silver Nanowires

In a 1,000 mL flask, 4.171 g of poly(N-vinylpyrrolidone) (trade name; Polyvinylpyrrolidone K30, MW: 40,000, Tokyo Kasei Kogyo Co., Ltd.), 70 mg of tetrabutylammonium chloride (Wako Pure Chemical Industries, Ltd.), 4.254 g of silver nitrate (Wako Pure Chemical Industries, Ltd.) and 500 mL of ethylene glycol (Wako Pure Chemical Industries, Ltd.) were put, and the resultant mixture was agitated for 15 minutes and uniformly dissolved, and then agitated at 110° C. for 16 hours in an oil bath, and thus a reaction mixture including silver nanowires was obtained.

Subsequently, the reaction mixture was returned to room temperature (25 to 30° C.), and then centrifuged by means of a centrifuge (As One Corporation), a reaction solvent was replaced with water, and thus dispersion aqueous solution I having 1% by weight of silver nanowires was obtained. According to the operation, unreacted silver nitrate, poly(N-vinylpyrrolidone) used as a mold, tetrabutylammonium chloride, ethylene glycol and silver nanoparticles having a small particle size in the reaction mixture were removed. Dispersion aqueous solution I having an arbitrary concentration of silver nanowires was obtained by redispersing precipitates on a filter paper into water. Mean values of length of the silver nanowires in a minor axis and in a major axis, and an aspect ratio thereof were 45 nanometers, 18 micrometers and 400, respectively.

### Preparation of a Binder Solution

In a 300 mL beaker whose tare weight was premeasured, 100 g of ultrapure water was put, and heating and agitation were carried out. At a liquid temperature of 80 to 90° C., 2.00 g of hydroxypropyl methyl cellulose (trade name; Metolose 90SH-10000, Shin-Etsu Chemical Co., Ltd., 100,000 mPa·s in viscosity of an aqueous solution having 2% by weight, hereinafter, abbreviated as HPMC) was put little by little, and the resultant mixture was agitated strongly to disperse HPMC uniformly. While keeping strong agitation, 80 g of ultrapure water was added, simultaneously heating was stopped, and agitation was continued while cooling the beaker with ice water until a uniform solution was formed. After agitation for 20 minutes, ultrapure water was added to be 200.00 g in weight of an aqueous solution, and agitation was further continued for 10 minutes at room temperature until a uniform solution was formed, and binder solution I having 1% by weight of HPMC was prepared.

### Preparation of a Composition for Forming a Transparent Conductive Film

Then, 17.1 g of binder solution I having 1% by weight, 17.1 g of dispersion aqueous solution I having 1% by weight of silver nanowires, 1.71 g of aqueous solution having 0.1% by weight of TritonX-100 (trade name) (Sigma-Aldrich Japan, Inc.) and 49.6 g of ultrapure water were weighed, the resultant mixture was agitated until a uniform solution was formed, and thus a composition for forming a transparent conductive film with a composition ratio as described below was obtained. The prepared composition showed a favorable dispersibility even after one week.

| | | |
|---|---|---|
| Silver nanowires | 0.20% | by weight |
| HPMC | 0.20% | by weight |
| Triton X-100 | 0.002% | by weight |
| Water | 99.598% | by weight |

### Preparation of a Transparent Conductive Film Substrate

Then, 1 mL of the coating forming composition obtained was added dropwise on 0.7 mm-thick Eagle XG glass (trade name) (Corning, Inc.) on a substrate surface of which was subjected to UV ozone treatment at an irradiation energy of 1,000 mJ/cm² (low pressure mercury lamp (254 nanometers)), and spin coating was performed at 500 rpm using a spin coater (trade name; MS-A150, Mikasa Inc.). Preliminary calcination of the glass substrate was performed on a hot stage at 50° C. under conditions of 90 seconds, and then major calcination was performed on a hot stage at 140° C. for 90 seconds, and thus transparent conductive film substrate I was prepared. Moreover, transparent conductive film substrate II was prepared in a manner similar to the substrate I except that spin coating was performed at 1,500 rpm.

Transparent conductive film substrate I obtained had a surface resistance value of 39.8Ω/□, a total luminous transmittance of 91.3% and a haze of 1.4%. Moreover, transparent conductive film substrate II obtained had a surface resistance value of 190Ω/□, a total luminous transmittance of 92.6% and a haze of 0.5%.

A solution containing a third component used in the invention was prepared as described below.

### Preparation of a Solution Containing the Third Component

Into a four-necked flask with a agitator, PGMEA as a polymerization solvent, methoxypolyethyleneglycol methacrylate as a radically polymerizable monomer, methacrylic acid, dicyclopentanyl methacrylate, N-cyclohexyl maleimide, and 2,2′-azobis(2,4-dimethylvaleronitrile) as a polymerization initiator were charged in the weight described below, and polymerization was performed by heating the resultant mixture at a polymerization temperature of 80° C. for 4 hours.

| | |
|---|---|
| PGMEA | 200.0 g |
| Methoxypolyethyleneglycol methacrylate | 10.0 g |
| Methacrylic acid | 30.0 g |
| Dicyclopentanyl methacrylate | 30.0 g |
| N-Cyclohexyl maleimide | 30.0 g |
| 2,2′-azobis(2,4-dimethylvaleronitrile) | 5.0 g |

A reaction mixture was cooled to room temperature, and polymer (A) solution I was obtained.

Part of solution was sampled and a weight average molecular weight was measured according to GPC analysis (polystyrene standard). As a result, the weight average molecular weight was 3,500.

### Example 1

### Preparation of a Photosensitive Composition

Then, 3.9 g of HP-7200HH (trade name) (an epoxy compound having a structure represented by formula (I), DIC, Inc., epoxy equivalent: 274 to 286) as a first component, 6.0 g of ARONIX M-450 (trade name) (Toagosei Co., Ltd.) (hereinafter, abbreviated as M450) as a second component, 22.4 g of polymer (A) solution I as a third component, 0.9 g of Irgacure 379 (trade name) (BASF Japan Ltd.) as a polymerization initiator, and 0.09 g of KP 341 (trade name) (Shin-Etsu Chemical Co., Ltd.) as a surfactant were weighed, 67.0 g of propylene glycol monomethyl ether acetate (hereinafter, abbreviated as PGMEA) as a solvent was added thereto, the resultant mixture was agitated until a uniform solution was formed, and thus photosensitive composition I having a composition ratio as described below was obtained.

| | |
|---|---|
| HP-7200HH | 3.9% by weight |
| M-450 | 6.0% by weight |
| Polymer (A) | 6.7% by weight |
| Irgacure 379 | 0.9% by weight |
| KP 341 | 0.1% by weight |
| PGMEA | 82.4% by weight |

### Formation of a Protective Film

On a transparent conductive film for transparent conductive film substrate I, 1 mL of photosensitive composition I obtained was added dropwise, and spin coating was performed at 500 rpm using a spin coater (trade name; MS-A150, Mikasa, Inc). The glass substrate was dried on a hot plate at 100° C. under a condition of 120 seconds. UV light was irradiated on the coating of the photosensitive composition from above under a condition of 50 mJ/cm², through a chromium-deposited photomask in which an opening pattern of a square 25 micrometers on a side was formed, using an exposure system (HB-20201CL model, an extra high pressure mercury lamp as a light source, USH-2004TO model, Ushio, Inc.). A coating after UV irradiation was immersed into an aqueous solution having 0.4% by weight of tetramethylammonium hydroxide (trade name; TMA-208, Kanto Chemical Co., Inc.) for 60 seconds. Then, the substrate was calcinated on a hot stage at 220° C. under a condition of 15 minutes, and transparent conductive film substrate I with a protective film was obtained.

Evaluation of the Transparent Conductive Film Substrate with the Protective Film

Transparent conductive film substrate I with the protective film obtained was evaluated as follows: a surface resistance value=41.5Ω/□; total luminous transmittance=90.8%; haze=1.5%; and protective film thickness=1.0 micrometer. Moreover, environmental resistance, hardness and patternability of the protective film were satisfactory (excellent). In a part on which a pattern was formed, a protective film pattern of a square 25 micrometers on a side was confirmed to have neither clipping nor flaking of patterns, and the protective film was confirmed to be subjected to patterning satisfactorily. Moreover, the transparent conductive film existed over the whole substrate, and no pattern was formed. The evaluation results are shown in Table 1.

### Example 2

### Formation of a Protective Film

A substrate obtained with a composition and in a manner similar to Example 1 was immersed into A1 etching solution (trade name) (Kanto Chemical Co., Inc.) for 30 seconds. Dry air was blown onto the coating and the substrate using an air gun to perform drying, and thus transparent conductive film substrate II with a protective film was obtained.

Evaluation of the Transparent Conductive Film Substrate with the Protective Film

Transparent conductive film substrate II with the protective film obtained was evaluated as follows: a surface resistance value=41.0Ω/□; total luminous transmittance=90.8% and haze=1.5%, and etching was confirmed to cause no decrease in conductivity and optical characteristics. Moreover, environmental resistance, hardness and patternability of the protective film were satisfactory (excellent). In a part on which a pattern was formed, a transparent conductive film pattern of a square 25 micrometers on a side was confirmed to have neither clipping nor flaking of patterns, and the transparent conductive film was confirmed to be subjected to patterning satisfactorily.

### Example 3

### Formation of a Protective Film

Transparent conductive film substrate III with a protective film was obtained with a composition and in a manner similar to Example 1 except that a calcinations temperature of 150° C. was applied.

Evaluation of the Transparent Conductive Film Substrate with the Protective Film

Transparent conductive film substrate III with the protective film obtained was evaluated as follows: a surface resistance value=40.0Ω/□; total luminous transmittance=90.7%, haze=1.5%, and protective film thickness=1.0 micrometer. Moreover, environmental resistance, hardness and patternability of the protective film were satisfactory (excellent). In a part on which a pattern was formed, a protective film pattern of a square 25 micrometers on a side was confirmed to have neither clipping nor flaking of patterns, and the protective film was confirmed to be subjected to patterning satisfactorily. Moreover, the transparent conductive film existed over the whole substrate, and no pattern was formed.

### Example 4

### Formation of a Protective Film

Transparent conductive film substrate IV with a protective film was obtained with a composition and in a manner similar to Example 3 except that UV light was irradiated through a photomask on a half region of which was subjected to chromium deposition.

Evaluation of the Transparent Conductive Film Substrate with the Protective Film

In an exposed region of transparent conductive film substrate IV with the protective film obtained, the substrate IV was evaluated as follows: a surface resistance value=40.1Ω/□, total luminous transmittance=90.7%, and haze=1.5%. In an unexposed region thereof, the substrate IV was evaluated as follows: a surface resistance value=39.4Ω/□, total luminous transmittance=90.7%, and haze=1.4%. Development was confirmed to cause no decrease in conductivity and optical characteristics. When a surface was observed using an incident-light microscope having a magnification of 500 times according to differential interferometry, the protective film existed on a surface in the exposed region, whereas, a residue of the protective film or the like was absent on a surface in the unexposed region, and thus the protective film was confirmed to be satisfactorily removed with a developer. Environmental resistance, hardness and patternability of the protective film were not evaluated.

### Example 5

### Formation of a Protective Film

A substrate obtained with a composition and in a manner similar to Example 3 was immersed into A1 etching solution (trade name) (Kanto Chemical Co., Inc.) for 30 seconds. Dry air was blown onto the coating and the substrate using an air gun to perform drying, and thus transparent conductive film substrate V with a protective film was obtained.

Evaluation of the Transparent Conductive Film Substrate with the Protective Film

Transparent conductive film substrate V with the protective film obtained was evaluated as follows: a surface resistance value=40.2Ω/□, total luminous transmittance=90.7%, haze=1.5%, and protective film thickness=1.0 micrometer. Moreover, environmental resistance, hardness and patternability of the protective film were satisfactory (excellent). In a part on which a pattern was formed, a transparent conductive film pattern of a square 25 micrometers on a side was confirmed to have neither clipping nor flaking of patterns, and the transparent conductive film was confirmed to be subjected to patterning satisfactorily.

### Example 6

### Preparation of a Photosensitive Composition

Then, 3.2 g of EP-4088S (trade name) (ADEKA Corporation, an epoxy compound represented by formula (I), epoxy equivalent: 170) as a first component, 8.7 g of M-450 (trade name) (Toagosei Co., Ltd.) (hereinafter, abbreviated as M450) as a second component, 29.0 g of polymer (A) solution I as a third component, 0.87 g of Irgacure 379 as a polymerization initiator, and 0.12 g of KP 341 as a surfactant were weighed, 79.0 g of PGMEA as a solvent was added thereto, the resultant mixture was agitated until a uniform solution was formed, and thus photosensitive composition II having a composition ratio as described below was obtained.

| | |
|---|---|
| EP-4088S | 2.7% by weight |
| M-450 | 7.2% by weight |
| Polymer (A) | 7.2% by weight |
| Irgacure 379 | 0.7% by weight |
| KP 341 | 0.1% by weight |
| PGMEA | 82.1% by weight |

### Formation of a Protective Film

Transparent conductive film substrate VI with a protective film was obtained with a composition and in a manner similar to Example 1 except that photosensitive composition II was used and a calcination temperature of 150° C. was applied.

Evaluation of the Transparent Conductive Film Substrate with the Protective Film

Transparent conductive film substrate VI with the protective film obtained was evaluated as follows: a surface resistance value=40.3Ω/□, total luminous transmittance=90.7%, haze=1.5%, and protective film thickness=1.0 micrometer. Moreover, environmental resistance was fairly satisfactory (good), and hardness and patternability of the protective film were satisfactory (excellent). In a part on which a pattern was formed, a protective film pattern of a square 25 micrometers on a side was confirmed to have neither clipping nor flaking of patterns, and the protective film was confirmed to be subjected to patterning satisfactorily. Moreover, the transparent conductive film existed over the whole substrate, and no pattern was formed.

### Example 7

### Formation of a Protective Film

A substrate obtained with a composition and in a manner similar to Example 6 was immersed into A1 etching solution (trade name) (Kanto Chemical Co., Inc.) for 30 seconds. Dry air was blown onto the coating and the substrate using an air gun to perform drying, and thus transparent conductive film substrate VII with a protective film was obtained.

Evaluation of the Transparent Conductive Film Substrate with the Protective Film

Transparent conductive film substrate VII with the protective film obtained was evaluated as follows: a surface resistance value=41.0Ω/□, total luminous transmittance=90.7%, and haze=1.5%. Etching was confirmed to cause no decrease in conductivity and optical characteristics. Moreover, environmental resistance was fairly satisfactory (good), hardness was satisfactory (excellent) and patternability of the protective film was fairly satisfactory (good).

### Example 8

### Formation of a Protective Film

Transparent conductive film substrate VIII with a protective film was obtained with a composition and in a manner similar to Example 3 except for using transparent conductive film substrate II.

Evaluation of the Transparent Conductive Film Substrate with the Protective Film

Transparent conductive film substrate VIII with the protective film obtained was evaluated as follows: a surface resistance value=191Ω/□, total luminous transmittance=92.0%, haze=0.4%, and protective film thickness=1.0 micrometer. Moreover, environmental resistance, hardness and patternability of the protective film were satisfactory (excellent). In a part on which a pattern was formed, a protective film pattern of a square 25 micrometers on a side was confirmed to have neither clipping nor flaking of patterns, and the protective film was confirmed to be subjected to patterning satisfactorily. Moreover, the transparent conductive film existed over the whole substrate, and no pattern was formed.

### Example 9

### Formation of a Protective Film

Transparent conductive film substrate IX with a protective film was obtained with a composition and in manner similar to Example 8 except that UV light was irradiated through a photomask on a half region of which was subjected to chromium deposition.

Evaluation of the Transparent Conductive Film Substrate with the Protective Film

In an exposed region of transparent conductive film substrate IX with the protective film, the substrate IX was evaluated as follows: a surface resistance value=192Ω/□, total luminous transmittance=92.0%, and haze=0.4%. In an unexposed region thereof, the substrate IX was evaluated as follows: a surface resistance value=190Ω/□, total luminous transmittance=92.0%, and haze=0.4%. Development was confirmed to cause no decrease in conductivity and optical characteristics. When a surface was observed using an incident-light microscope having a magnification of 500 times according to differential interferometry, the protective film existed on a surface in the exposed region, on the contrary, a residue of the protective film or the like was absent on a surface in the unexposed region, and thus the protective film was confirmed to be satisfactorily removed with a developer. Environmental resistance, hardness and patternability of the protective film were not evaluated.

### Example 10

### Formation of a Protective Film

A substrate obtained with a composition and in a manner similar to Example 8 was immersed into A1 etching solution (trade name) (Kanto Chemical Co., Inc.) for 30 seconds. Dry air was blown onto the coating and the substrate using an air gun to perform drying, and thus transparent conductive film substrate X with a protective film was obtained.

Evaluation of the Transparent Conductive Film Substrate with the Protective Film

Transparent conductive film substrate X with the protective film obtained was evaluated as follows: a surface resistance value=191Ω/□, total luminous transmittance=92.0%, haze=0.5%, and protective film thickness=1.0 micrometer. Moreover, environmental resistance, hardness and patternability of the protective film were satisfactory (excellent). In a part on which a pattern was formed, a transparent conductive film pattern of a square 25 micrometers on a side was confirmed to have neither clipping nor flaking of patterns, and the protective film was confirmed to be subjected to patterning satisfactorily.

### Comparative Example 1

When a protective film was formed neither on transparent conductive film substrate I nor on transparent conductive film substrate II and the substrates were evaluated, both of the substrates had poor (bad) environmental resistance and hardness.

The substrates were not protected with the protective film in Comparative Example 1, and therefore environmental resistance and hardness were confirmed to be poor (bad).

### Comparative Example 2

Then, 4.0 g of VG-3101L (trade name) (an epoxy compound having a bisphenol A structure, Printec Co., Ltd., epoxy equivalent: 201 to 215), 8.4 g of M-450, 28.0 g of polymer (A) solution I, 0.84 g of Irgacure 379 and 0.12 g of KP 341 were weighed, 79.0 of PGMEA as a solvent was added thereto, and the resultant mixture was agitated until a uniform solution was formed, and thus photosensitive composition III having a composition ratio as described below was obtained.

| | |
|---|---|
| VG-3101L | 3.3% by weight |
| M-450 | 7.0% by weight |
| Polymer (A) | 7.0% by weight |
| Irgacure 379 | 0.7% by weight |
| KP 341 | 0.1% by weight |
| PGMEA | 81.9% by weight |

### Formation of a Protective Film

Transparent conductive film substrate XI with a protective film was obtained in a manner similar to Example 1 except that photosensitive composition III was used and a calcination temperature of 150° C. was applied.

Evaluation of the Transparent Conductive Film Substrate with the Protective Film

Transparent conductive film substrate XI with the protective film obtained was evaluated as follows: a surface resistance value=40.8Ω/□, total luminous transmittance=90.9%, haze=1.4%, and protective film thickness=1.0 micrometer. Moreover, environmental resistance was poor (bad), and hardness and patternability of the protective film were satisfactory (excellent).

In Comparative Example 2, the environmental resistance was confirmed to be poor due to use of the epoxy compound without including a structure represented by formula (I).

### Comparative Example 3

Then, 5.2 g of RIKARESIN BPO-20E (trade name) (an epoxy compound having a bisphenol A structure, New Japan Chemical Co., Ltd., epoxy equivalent: 310 to 340), 7.3 g of M-450, 24.0 g of polymer (A) solution I, 0.73 g of Irgacure 379 and 0.12 g of KP 341 were weighed, and 79.0 g of PGMEA as a solvent was added thereto, the resultant mixture was agitated until a uniform solution was formed, and thus photosensitive composition IV having a composition ratio as described below was obtained.

| | |
|---|---|
| RIKARESIN BPO-20E | 4.5% by weight |
| M-450 | 6.3% by weight |
| Polymer (A) | 6.2% by weight |
| Irgacure 379 | 0.6% by weight |
| KP 341 | 0.1% by weight |
| PGMEA | 82.3% by weight |

### Formation of a Protective Film

Transparent conductive film substrate XII with a protective film was obtained in a manner similar to Example 1 except that photosensitive composition IV was used and a calcination temperature of 150° C. was applied.

Evaluation of the Transparent Conductive Film Substrate with the Protective Film

Transparent conductive film substrate XII with the protective film obtained was evaluated as follows: a surface resistance value=41.0Ω/□, total luminous transmittance=90.9%, haze=1.5%, and protective film thickness=1.0 micrometer. Moreover, environmental resistance was poor (bad). Hardness and patternability of the protective film were satisfactory (excellent).

In Comparative Example 3, the environmental resistance was confirmed to be poor due to use of the epoxy compound without including a structure represented by formula (I).

### Comparative Example 4

### Formation of a Protective Film

A substrate obtained with a composition and in a manner similar to Comparative Example 3 was further immersed into A1 etching solution (trade name) (Kanto Chemical Co., Inc.) for 30 seconds. Dry air was blown onto the coating and the substrate using an air gun to perform drying, and thus transparent conductive film substrate XIII with a protective film was obtained.

Evaluation of the Transparent Conductive Film Substrate with the Protective Film

Transparent conductive film substrate XIII with the protective film obtained had a surface resistance value over a measurement upper limit, and therefore the surface resistance could not be measured. Thus, a decrease in conductivity was confirmed. Moreover, the substrate XIII was evaluated as follows: total luminous transmittance=93.4%, haze=0.5%, and protective film thickness=1.0 micrometer. Hardness was satisfactory (excellent). Patternability of the transparent conductive film was poor (bad). The transparent conductive film was removed over the whole substrate, and no pattern was formed.

In Comparative Example 4, a decrease in conductivity by patterning of the transparent conductive film was confirmed and patternability of the transparent conductive film was confirmed to be poor due to use of the epoxy compound without including a structure represented by formula (I).

### Comparative Example 5

### Preparation of a Photosensitive Composition

Based on JP 2010-507199 A, a photosensitive composition was prepared in the procedure described below.

Then, 36.6 g of tripropylene glycol diacrylate (hereinafter, abbreviated as TPGDA), 11.0 g of phosphoric acid trimethylol triacrylate (hereinafter, abbreviated as TMPTA), 2.45 g of Irgacure 754 (trade name) (BASF Japan Ltd.) and 0.015 g of 4-methoxyphenol were weighed, 200 g of PGMEA as a solvent was added thereto, the resultant mixture was agitated until a uniform solution was formed, and thus photosensitive composition V having a composition as described below was obtained.

| | | |
|---|---|---|
| TPGDA | 14.6% | by weight |
| TMPTA | 4.4% | by weight |
| Irgacure 754 | 1.0% | by weight |
| 4-Methoxyphenol | 0.06% | by weight |
| PGMEA | 79.94% | by weight |

### Formation of a Protective Film

Transparent conductive film substrate XIV with a protective film was obtained in a manner similar to Example 1 except that photosensitive composition V was used and a calcination temperature of 150° C. was applied.

Evaluation of the Transparent Conductive Film Substrate with the Protective Film

Transparent conductive film substrate XIV with the protective film obtained was evaluated as follows: a surface resistance value=40.3Ω/□, total luminous transmittance=91.0%, haze=1.6%, and protective film thickness=1.6 micrometer. Moreover, hardness was somewhat poor (marginal), environmental resistance was poor (bad) and patternability was satisfactory (excellent).

In Comparative Example 5, hardness and environmental resistance were confirmed to be poor due to a component constitution different from a component constitution of the invention.

TABLE 1

| | | Transparency | | | | | |
|---|---|---|---|---|---|---|---|
| | Conductivity | Total | | | | Patternability | |
| | Surface | luminous | | | | | Transparent |
| | resistance | transmittance | Haze | | Environmental | Protective | conductive |
| | (Q/□) | (%) | (%) | Hardness | resistance | film | film |
| Example 1 | 41.5 | 90.8 | 1.5 | Excellent | Excellent | Excellent | — |
| Example 2 | 41.0 | 90.8 | 1.5 | Excellent | Excellent | — | Excellent |
| Example 3 | 40.0 | 90.7 | 1.5 | Excellent | Excellent | Excellent | — |
| Example 4 | 40.1 | 90.7 | 1.5 | — | — | — | — |
| (exposed | | | | | | | |
| region) | | | | | | | |
| Example 4 | 39.4 | 90.7 | 1.4 | — | — | — | — |
| (unexposed | | | | | | | |
| region) | | | | | | | |
| Example 5 | 40.2 | 90.7 | 1.4 | Excellent | Excellent | — | Excellent |
| Example 6 | 40.3 | 90.7 | 1.5 | Excellent | Good | Excellent | — |
| Example 7 | 41.0 | 90.7 | 1.5 | Excellent | Good | — | Good |
| Example 8 | 191 | 92.0 | 0.4 | Excellent | Excellent | Excellent | — |
| Example 9 | 192 | 92.0 | 0.4 | — | — | — | — |
| (exposed | | | | | | | |
| region) | | | | | | | |
| Example 9 | 190 | 92.0 | 0.4 | — | — | — | — |
| (unexposed | | | | | | | |
| region) | | | | | | | |
| Example 10 | 191 | 92.0 | 0.5 | Excellent | Excellent | — | Excellent |
| Comparative | — | — | — | Bad | Bad | — | — |
| Example 1 | | | | | | | |
| Comparative | 40.8 | 90.9 | 1.4 | Excellent | Bad | Excellent | — |
| Example 2 | | | | | | | |
| Comparative | 41.0 | 90.9 | 1.5 | Excellent | Bad | Excellent | — |
| Example 3 | | | | | | | |
| Comparative | — | 93.4 | 0.5 | Excellent | — | — | Bad |
| Example 4 | | | | | | | |
| Comparable | 40.3 | 91.0 | 1.6 | Marginal | Bad | Excellent | — |
| Example 5 | | | | | | | |

Although the invention has been described and illustrated with a certain degree of particularity, it is understood that the disclosure has been made only by way of example, and that numerous changes in the conditions and order of steps can be resorted to by those skilled in the art without departing from the spirit and scope of the invention.

### INDUSTRIAL APPLICABILITY

A protective film for a transparent conductive film of the invention can be used in a manufacturing process of device elements, such as a liquid crystal display device, an organic electroluminescence display, an electronic paper, a touch panel device and a photovoltaic device.

What is claimed is:

1. A photosensitive composition that is used as a protective film for a transparent conductive film including a nanostructure, and contains
a compound including a structure represented by general formula (I) in a molecule and having an epoxy group or oxetanyl group in the molecule as a first component,
a compound including a (meth)acryl group in the molecule as a second component,
an alkali-soluble polymer as a third component, and
a solvent as a fourth component:

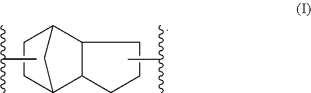

2. The photosensitive composition according to claim 1, used for patterning of the transparent conductive film including the nano structure.

3. The photosensitive composition according to claim 1, wherein an equivalent of the epoxy group or oxetanyl group of the first component is 200 or more, and the number of the epoxy groups or oxetanyl groups in one molecule is 2 or more.

4. The photosensitive composition according to claim 1, wherein the first component is a compound represented by general formula (I-a): 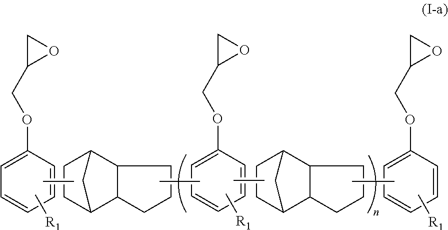
wherein R₁ in formula (I-a) is each independently hydrogen or a hydrocarbon group having 1 to 12 carbons, and n is an integer from 1 to 10 to represent a repeating unit.

5. The photosensitive composition according to claim 1, wherein the second component is a compound represented by general formula (II-a): 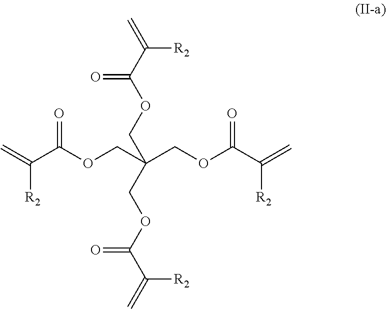
wherein R₂ in formula (II-a) is each independently hydrogen or an alkyl group having 1 to 4 carbons.

6. The photosensitive composition according to claim 1, wherein the third component is a polymer obtained by copolymerizing a mixture containing a radically polymerizable monomer having a carboxyl group.

7. The photosensitive composition according to claim 6, wherein the third component is a polymer obtained by copolymerizing a mixture containing (meth)acrylic acid, N-cyclohexyl maleimide and dicyclopentanil(meth)acrylate.

8. The photosensitive composition according to claim 1, wherein a ratio of the first component is in the range of 1 to 10% by weight, a ratio of the second component is in the range of 1 to 10% by weight, a ratio of the third component is in the range of 1 to 10% by weight, and a ratio of the fourth component is in the range of 70 to 97% by weight, based on the total amount of the photosensitive composition.

9. The photosensitive composition according to claim 1, further containing a photopolymerization initiator.

10. The photosensitive composition according to claim 1, wherein the nanostructure includes silver nanowires.

11. The photosensitive composition according to claim 10, wherein a mean of length of the silver nanowires in a minor axis is in the range of 5 nanometers to 100 nanometers, and a mean of length of the silver nanowires in a major axis is in the range of 2 micrometers to 50 micrometers.

12. A method for forming a protective film for a transparent conductive film including a nanostructure, comprising:
process 1, a process for applying the photosensitive composition according to claim 1 onto the transparent conductive film including the nanostructure, and obtaining a coating;
process 2 for drying the coating;
process 3 for irradiating the coating with light through a photomask;
process 4 for developing the coating using a developer; and
process 5 for heating the coating.

13. A method for patterning a transparent conductive film including a nanostructure, applying the method according to claim 12, and further comprising a process for etching the transparent conductive film including the nanostructure by using an acidic solution after process 4.

14. The method for patterning the transparent conductive film according to claim 13, wherein the acidic solution contains phosphoric acid.

15. The method according to claim 12, wherein a heating temperature is 160° C. or lower in process 5.

16. The method for patterning the transparent conductive film according to claim 13, wherein a heating temperature is 160° C. or lower in process 5.

17. A laminate including a film formed by the method according to claim 12, a transparent conductive film including a nanostructure, and a substrate, wherein surface resistance of the transparent conductive film is in the range of 10Ω/□ to 500Ω/□, a total luminous transmittance of the laminate is 85% or more, and a haze of the laminate is 3% or less.

18. An electronic device using the laminate according to claim 17.
